(19) United States
(12) Patent Application Publication
(10) Pub. No.: US 2022/0417700 A1
(43) Pub. Date: Dec. 29, 2022

(54) VEHICLE, SERVER, CONTROL METHOD OF VEHICLE AND CONTROL METHOD OF SERVER

(71) Applicants: HYUNDAI MOTOR COMPANY, Seoul (KR); KIA CORPORATION, Seoul (KR)

(72) Inventors: Sang Heun LEE, Seoul (KR); Yoonsoo KIM, Seoul (KR)

(73) Assignees: Hyundai Motor Company, Seoul (KR); KIA CORPORATION, Seoul (KR)

(21) Appl. No.: 17/847,554

(22) Filed: Jun. 23, 2022

(30) Foreign Application Priority Data
Jun. 25, 2021 (KR) 10-2021-0083026

(51) Int. Cl. H04W 4/021; H04H 20/71

(52) U.S. Cl. CPC H04W 4/021; H04H 20/71

(57) ABSTRACT

A vehicle includes: a communication device; an audio device; a global positioning system; and a control device configured to receive radio station information from a server through the communication device, the radio station information including information on a plurality of areas, radio frequencies for each of the plurality of areas, and a plurality of radio station names corresponding to each of the radio frequencies, identify location information of the vehicle based on a signal received through the global positioning system, receive a first signal of a first radio frequency through the audio device, and change a setting of a radio frequency of the audio device, based on the first radio frequency, the radio station information, and the location information of the vehicle, in response to a field strength of the first signal being equal to or less than a reference field strength.

### CROSS-REFERENCE TO RELATED APPLICATION

This application is based on and claims priority under 35 U.S.C. § 119 to Korean Patent Application No. 10-2021-0083026, filed on Jun. 25, 2021 in the Korean Intellectual Property Office, the disclosure of which is incorporated herein by reference.

### TECHNICAL FIELD

The disclosure relates to a vehicle, a server, a control method of the vehicle and a control method of the server.

### BACKGROUND

An audio device may be installed in a vehicle, and an occupant (also referred to as a user) of the vehicle may listen to a radio broadcast through the audio device.

For instance, an audio device in a vehicle may receive a radio frequency signal by searching for and setting a radio frequency of a radio broadcast receivable in an area where the vehicle is driving.

When listening to a radio broadcast through a conventional audio device in a vehicle, as the vehicle moves away from a radio transmitting station, a signal received by the vehicle from the radio transmitting station is weakened due to attenuation of radio waves and noise of the signal increases.

### SUMMARY

An aspect of the disclosure provides a vehicle, a server, a control method of the vehicle and a control method of the server that may automatically change a frequency of a radio broadcast when a signal received from a base station of the radio broadcast is weakened.

For instance, the vehicle, the server, the control method of the vehicle and the control method of the server may, when a signal received from a transmitting station in a first area of a radio broadcast is weakened due to a movement of the vehicle which is driving, automatically search for a frequency of the radio broadcast of a transmitting station in a second area of the same broadcasting station as the radio broadcast that an occupant is currently listening to, change to the searched frequency, and thereby may enable the occupant to continuously listen to the radio broadcast that the occupant is currently listening to.

For instance, the vehicle, the server, the control method of the vehicle and the control method of the server may, when a signal received from a transmitting station in a first area of a radio broadcast is weakened and a radio broadcast of a transmitting station in a second area of the same broadcasting station as the radio broadcast that an occupant is currently listening to is different from the radio broadcast that the occupant is currently listening to, output information to notify the occupant.

Additional aspects of the disclosure will be set forth in part in the description which follows and, in part, will be obvious from the description, or may be learned by practice of the disclosure.

According to an aspect of the disclosure, there is provided a vehicle, including: a communication device; an audio device; a global positioning system; and a control device configured to receive radio station information from a server through the communication device, the radio station information including information on a plurality of areas, radio frequencies for each of the plurality of areas, and a plurality of radio station names corresponding to each of the radio frequencies, identify location information of the vehicle based on a signal received through the global positioning system, receive a first signal of a first radio frequency through the audio device, and change a setting of a radio frequency of the audio device, based on the first radio frequency, the radio station information, and the location information of the vehicle, in response to a field strength of the first signal being equal to or less than a reference field strength.

The control device is configured to identify a second radio frequency corresponding to a radio station name identical to at least one first radio station name of the first radio frequency, among the plurality of radio station names corresponding to each of the radio frequencies included in the radio station information, in response to the field strength of the first signal being equal to or less than the reference field strength, and change the radio frequency of the audio device from the first radio frequency to the second radio frequency, in response to the identifying of the second radio frequency.

The audio device includes a main tuner and a sub tuner, the first signal is received through the main tuner, and the control device is configured to identify at least one radio frequency settable in the audio device through the sub tuner, identify at least one second radio station name corresponding to each of the at least one radio frequencies, based on the radio station information, and identify the second radio frequency corresponding to the radio station name identical to the at least one first radio station name of the first radio frequency, among the at least one second radio station name corresponding to each of the at least one radio frequencies, in response to the field strength of the first signal being equal to or less than the reference field strength.

The control device is configured to identify the at least one first radio station name corresponding to the first radio frequency based on the radio station information.

A second signal of the second radio frequency is received through the sub tuner, and the control device is configured to change the radio frequency of the audio device from the first radio frequency to the second radio frequency based on the first signal and the second signal corresponding to each other.

The vehicle further including: an output device, and wherein the control device is configured to receive the second signal of the second radio frequency through the main tuner, in response to changing the radio frequency of the audio device from the first radio frequency to the second radio frequency, and control the output device to output a signal corresponding to the second signal.

According to an aspect of the disclosure, there is provided a server, including: a communicator; a storage configured to store radio station information including location information on a plurality of transmitting stations, radio frequencies for each of the plurality of transmitting stations, location information of a plurality of vehicles corresponding to each of the plurality of transmitting stations, and at least one radio station name corresponding to each of the radio frequencies; and a controller configured to receive location information of a vehicle and a radio frequency corresponding to the location information of the vehicle, from the vehicle through the communicator, run a machine learning algorithm which is pre-trained to predict, based on the received location information and the received radio frequency, a first transmitting station corresponding to the received location information among the plurality of transmitting stations, store the location information of the vehicle in the storage to correspond to the first transmitting station and update the radio station information, and transmit the updated radio station information to the vehicle through the communicator.

The controller is configured to run the machine learning algorithm to identify at least one transmitting station corresponding to the received radio frequency among the plurality of transmitting stations, and to predict that the first transmitting station corresponds to the received location information, in response to the received location information being included in a predetermined first radio wave detection area of the first transmitting station among the at least one transmitting station.

The controller is configured to run the machine learning algorithm to identify a predetermined number of vehicles located adjacent to the received location information among vehicles corresponding to each of the at least one transmitting stations, in response to the received location information not being included in a predetermined radio wave detection area of each of the at least one transmitting stations, and to predict that the first transmitting station in which a largest number of vehicles are included among the identified vehicles corresponds to the received location information.

The machine learning algorithm includes a K-nearest neighbors algorithm.

According to an aspect of the disclosure, there is provided a control method of a vehicle, the control method including: receiving, from a server, radio station information including information on a plurality of areas, radio frequencies for each of the plurality of areas, and a plurality of radio station names corresponding to each of the radio frequencies, identifying location information of the vehicle based on a signal received through a global positioning system of the vehicle, receiving a first signal of a first radio frequency through an audio device of the vehicle, and changing a setting of a radio frequency of the audio device, based on the first radio frequency, the radio station information, and the location information of the vehicle, in response to a field strength of the first signal being equal to or less than a reference field strength.

The changing of the setting of the radio frequency of the audio device includes: identifying a second radio frequency corresponding to a radio station name identical to at least one first radio station name of the first radio frequency, among the plurality of radio station names corresponding to each of the radio frequencies included in the radio station information, in response to the field strength of the first signal being equal to or less than the reference field strength, and changing the radio frequency of the audio device from the first radio frequency to the second radio frequency, in response to the identifying of the second radio frequency.

The first signal is received through a main tuner of the audio device, the control method further includes identifying at least one radio frequency settable in the audio device through a sub tuner of the audio device, and identifying at least one second radio station name corresponding to each of the at least one radio frequencies, based on the radio station information, and the identifying of the second radio frequency includes identifying the second radio frequency corresponding to the radio station name identical to the at least one first radio station name of the first radio frequency, among the at least one second radio station name corresponding to each of the at least one radio frequencies, in response to the field strength of the first signal being equal to or less than the reference field strength.

The identifying of the second radio frequency includes: identifying the at least one first radio station name corresponding to the first radio frequency based on the radio station information.

A second signal of the second radio frequency is received through the sub tuner, and the changing of the setting of the radio frequency of the audio device changes the radio frequency of the audio device from the first radio frequency to the second radio frequency based on the first signal and the second signal corresponding to each other.

The control method further including: receiving the second signal of the second radio frequency through the main tuner, in response to changing the radio frequency of the audio device from the first radio frequency to the second radio frequency, and controlling an output device of the vehicle to output a signal corresponding to the second signal.

According to an aspect of the disclosure, there is provided a control method of a server, the control method including: storing radio station information including location information on a plurality of transmitting stations, radio frequencies for each of the plurality of transmitting stations, location information of a plurality of vehicles corresponding to each of the plurality of transmitting stations, and at least one radio station name corresponding to each of the radio frequencies; receiving, from a vehicle, location information of the vehicle and a radio frequency corresponding to the location information of the vehicle; running a machine learning algorithm which is pre-trained to predict, based on the received location information and the received radio frequency. a first transmitting station corresponding to the received location information among the plurality of transmitting stations; storing the location information of the vehicle in a storage to correspond to the first transmitting station and updating the radio station information; and transmitting the updated radio station information to the vehicle.

The running of the machine learning algorithm includes: identifying at least one transmitting station corresponding to the received radio frequency among the plurality of transmitting stations, and predicting that the first transmitting station corresponds to the received location information, in response to the received location information being included in a predetermined first radio wave detection area of the first transmitting station among the at least one transmitting station.

The running of the machine learning algorithm includes identifying a predetermined number of vehicles located adjacent to the received location information among vehicles corresponding to each of the at least one transmitting stations, in response to the received location information not being included in a predetermined radio wave detection area of each of the at least one transmitting stations, and predicting that the first transmitting station in which a largest number of vehicles are included among the identified vehicles corresponds to the received location information.

The machine learning algorithm includes a K-nearest neighbors algorithm.

### BRIEF DESCRIPTION OF THE DRAWINGS

These and/or other aspects of the disclosure will become apparent and more readily appreciated from the following description of the embodiments, taken in conjunction with the accompanying drawings of which:

FIG. 1 is a block diagram illustrating a system according to an embodiment;

FIG. 2 is a block diagram illustrating a vehicle according to an embodiment;

FIG. 3 is a block diagram illustrating an audio device of a vehicle according to an embodiment;

FIGS. 4 to 7 are diagrams illustrating radio station information stored in a server according to an embodiment;

FIG. 8 is a flowchart illustrating operations of a server according to an embodiment;

FIG. 9 is a flowchart illustrating operations of a vehicle according to an embodiment;

FIG. 10 is a flowchart illustrating operations of a vehicle according to an embodiment;

FIG. 11 is a diagram illustrating a display screen of an audio device of a vehicle according to an embodiment; and

FIG. 12 is a diagram illustrating radio station information according to an embodiment.

### DETAILED DESCRIPTION

Like reference numerals throughout the specification denote like elements. Also, this specification does not describe all the elements according to embodiments of the disclosure, and descriptions well-known in the art to which the disclosure pertains or overlapped portions are omitted. The terms such as “˜part”, “˜device”, “˜module”, and the like may refer to a unit for processing at least one function or act. For example, the terms may refer to at least process processed by at least one hardware or software. According to embodiments, a plurality of “˜parts”, “˜devices”, or “˜modules” may be embodied as a single element, or a single of “˜part”, “˜device”, or “˜module” may include a plurality of elements.

It will be understood that when an element is referred to as being “connected” to another element, it can be directly or indirectly connected to the other element, wherein the indirect connection includes “connection” via a wireless communication network.

It will be understood that the terms “include” when used in this specification, specify the presence of stated features, integers, steps, operations, elements, and/or components, but do not preclude the presence or addition of one or more other features, integers, steps, operations, elements, components, and/or groups thereof.

It will be understood that, although the terms first, second, etc. may be used herein to describe various elements, these elements should not be limited by these terms.

It is to be understood that the singular forms are intended to include the plural forms as well, unless the context clearly dictates otherwise.

Reference numerals used for method steps are just used for convenience of explanation, but not to limit an order of the steps. Thus, unless the context clearly dictates otherwise, the written order may be practiced otherwise.

Hereinafter, an operation principle and embodiments will be described in detail with reference to the accompanying drawings.

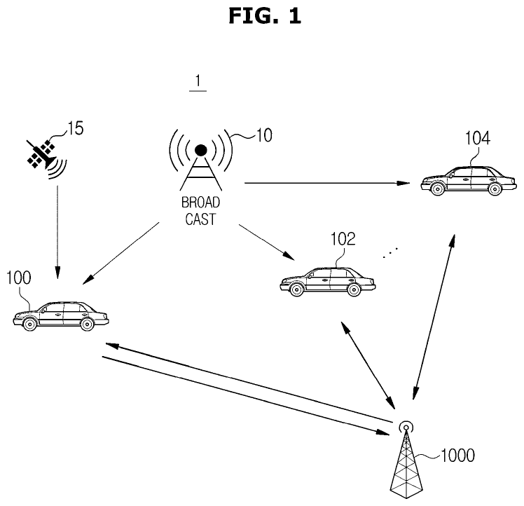

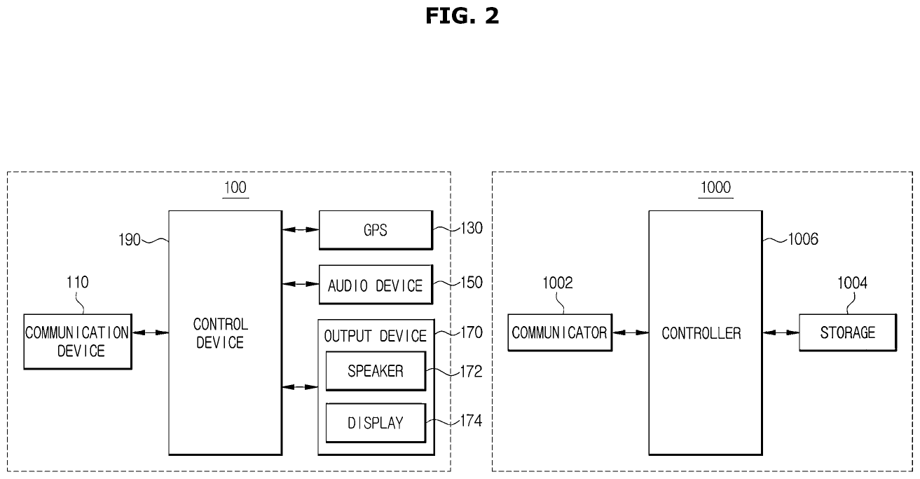

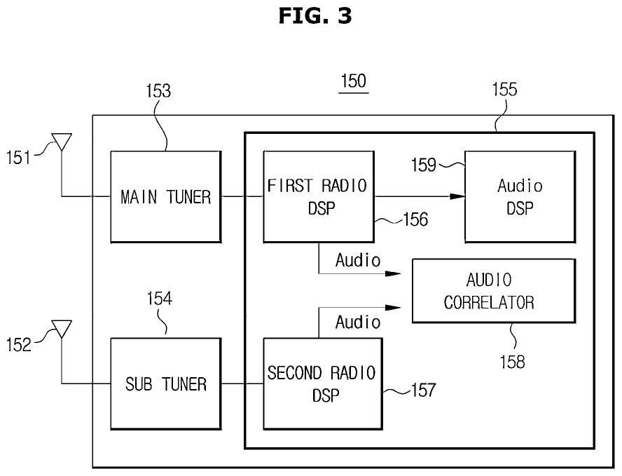

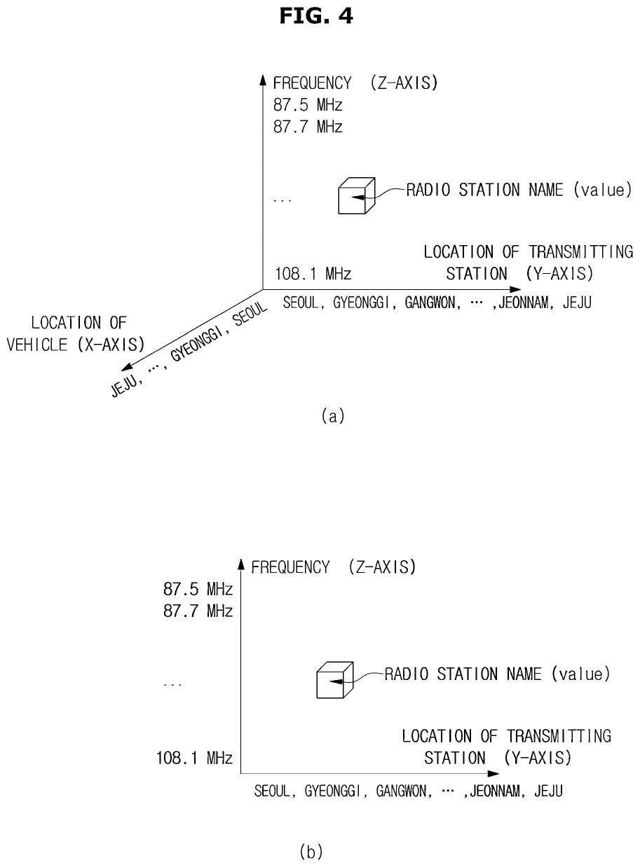

FIG. 1 is a block diagram illustrating a system 1 according to an embodiment. FIG. 2 is a block diagram illustrating a vehicle 100 according to an embodiment. FIG. 3 is a block diagram illustrating an audio device 150 of the vehicle 100 according to an embodiment. FIGS. 4 to 7 are diagrams illustrating radio station information stored in a server 1000 according to an embodiment.

Referring to FIG. 1, the system 1 may include at least one vehicle, e.g., a first vehicle 100, a second vehicle 102, an m^{th} vehicle 104, and/or a server 1000.

Each of the at least one vehicle, for example, each of the first vehicle 100, the second vehicle 102, and the m^{th} vehicle 104, may select (or set) a radio frequency of the audio device 150, based on radio station information received from the server 1000, location information of its own, and/or a field strength of a signal of a radio frequency received from the audio device of its own.

For instance, the first vehicle 100 driving in a first area may receive a first signal of a first radio frequency from a transmitting station 10 and output a sound signal corresponding to the first signal through a speaker. Accordingly, an occupant of the first vehicle 100 may listen to a first radio broadcast of the first radio frequency.

The first vehicle 100 may identify a field strength of the first signal of the first radio frequency, while receiving the first signal of the first radio frequency, and also identify whether the field strength of the first signal is equal to or less than a predetermined reference field strength.

For instance, when the first vehicle 100 moves from the first area to a second area, the first signal of the first radio frequency set in the first area may be weakened, and thus the field strength of the first signal may be equal to or less than the predetermined reference field strength.

When the field strength of the first signal is equal to or less than the predetermined reference field strength, the first vehicle 100 may change a setting of a radio frequency based on the first radio frequency, location information of the first vehicle 100 and/or the radio station information received from the server 1000, and thereby may allow the occupant to continuously listen to the first radio broadcast that is listening to without interruption.

For example, when radio broadcast of two radio frequencies is the same, the first vehicle 100 may change the setting of the radio frequency, i.e., switch the radio frequency between the two radio frequencies, so that the occupant may continuously listen to the first radio broadcast that is listening to.

Referring to FIG. 2, the at least one vehicle, e.g., the first vehicle 100 may include a communication device 110, a global positioning system (GPS, also referred to as a global navigation satellite system (GNSS)) 130, the audio device 150, an output device 170, and/or a control device 190.

The communication device 110 (also referred to as a communication circuit) may establish wireless and/or wired communication channel between an external device such as the server 1000 and an electronic device (not shown), support communication through the established communication channel, and also include a communication circuit.

For example, the communication device 110 may include a wired communication module (e.g., a power line communication module) and/or a wireless communication module (e.g., a cellular communication module, a Wi-Fi communication module, and/or a local wireless communication module) and communicate with the external device using a corresponding communication module among the communication modules above.

The communication device 110 may further include a communication circuit (also referred to as a transceiver) capable of performing communication among constituent components (also referred to as devices) of the first vehicle 100, e.g., a controller area network (CAN) communication and/or a local interconnect network (LIN) communication, and a control circuit that controls operations of the communication circuit.

The GPS 130 (also referred to as a GNSS) may receive a satellite signal propagated from a satellite 15 of the GNSS or the GPS, and the satellite signal may include position coordinates of the first vehicle 100.

The audio device 150 may include a radio function for receiving and outputting a broadcast signal transmitted from the transmitting station 10 of a radio broadcaster, and an audio function for reproducing a sound source stored in a storage device (not shown, e.g., a compact disc (CD) or a storage medium) of the first vehicle 100 or a sound source received through the communication device 110.

Referring to FIG. 3, the audio device 150 may include a first antenna 151, a second antenna 152, a main tuner 153 electrically connected to the first antenna 151, a sub tuner 154 electrically connected to the second antenna 152 and/or a signal processor 155.

The first and second antennas 151 and 152 may receive a signal transmitted from a transmitting station of each radio broadcaster.

The main tuner 153 may receive a signal of a radio frequency corresponding to a selected radio channel (also referred to as a radio program)

The sub tuner 154 may receive a signal of at least one radio frequency settable in the audio device 150.

The sub tuner 154 may identify the at least one radio frequency settable in the audio device 150, i.e., a valid radio frequency, based on field strengths of signals of all frequencies received through the second antenna 152. For instance, the sub tuner 154 may identify a radio frequency of a signal having a field strength greater than the predetermined reference field strength as the valid radio frequency.

The signal processor 155 may signal-process a signal transmitted from the main tuner 153 and/or the sub tuner 154 and transmit signal processing information to the control device 190.

The signal processor 155 may transmit the signal of the radio frequency received from the main tuner 153 to a speaker (not shown) of the first vehicle 100, based on control of the control device 190, so that the speaker may output the signal.

The signal processor 155 may include a first radio digital signal processor (DSP) 156 electrically connected to the main tuner 153, a second radio DSP 157 electrically connected to the sub tuner 154, an audio correlator 158, and/or an audio DSP 159.

The first radio DSP 156 may signal-process the signal received from the main tuner 153 and transmit the signal to the audio correlator 158 and/or the audio DSP 159.

The second radio DSP 157 may signal-process the signal received from the sub tuner 154 and transmit the signal to the audio correlator 158.

The audio correlator 158 may identify a correlation between a signal transmitted from the first radio DSP 156 and a signal transmitted from the second radio DSP 157 and transmit correlation information to the control device 190. For example, the correlation information may be used for radio frequency change.

The audio DSP 159 may signal-process the signal transmitted from the first radio DSP 156 and transmit the signal to the output device 170 of the first vehicle 100.

The output device 170 may include a speaker 172 and a display 174.

The speaker 172 may output a sound signal based on the control of the control device 190.

The speaker 172 may output a signal of radio frequency transmitted from the audio device 150. For example, the speaker 172 may output a signal received through the main tuner 153 of the audio device 150 as the sound signal.

The display 174 may display various types of content (e.g., a text, an image, a video, an icon, and/or a symbol, and the like). The display 174 may include a touch screen, and receive an input such as a touch, gesture, proximity or hovering input using a user's body part.

The display 174 may display visual information related to setting and/or output of the audio device 150.

The control device 190 (also referred to as a control circuit or a processor) may control at least one other constituent component (e.g., a hardware constituent component or a software constituent component (software program)) of the first vehicle 100. Also, the control device 190 may perform various data processing and data operations.

The control device 190 may include a processor and a memory.

The control device 190 may receive the radio station information from the server 1000 through the communication device 110.

The radio station information may include information on a plurality of areas, locations of transmitting stations of radio broadcasters of each of the plurality of areas, radio frequencies for each of the plurality of areas, and/or a plurality of radio station names corresponding to each of the radio frequencies. For instance, the information on the plurality of areas may correspond to location information of each vehicle and each of the radio frequencies may correspond to each of the transmitting stations.

The control device 190 may identify the location information of the first vehicle 100 based on a signal received through the GPS 130.

The control device 190 may receive the first signal of the first radio frequency through the audio device 150.

For instance, the control device 190 may receive the first signal of the first radio frequency through the main tuner 153 of the audio device 150, and control a sound signal corresponding to the first signal to be output through the speaker 172 of the output device 170.

The control device 190 may transmit the location information of the first vehicle 100, information related to reception of a radio broadcast corresponding to the location information and/or other information to the server 1000.

For example, the information related to the reception of the radio broadcast corresponding to the location information may include a radio frequency of a radio broadcast that the first vehicle 100 is listening to at a corresponding location, a field strength of a signal of the radio frequency, and/or a radio station name of the radio frequency.

For example, the other information may include current time information and/or vehicle information.

The control device 190 may identify at least one radio frequency settable in the audio device 150 through the sub tuner 154 of the audio device 150.

The control device 190 may identify the field strength of the first signal.

In response to the field strength of the first signal being equal to or less than the predetermined reference field strength, the control device 190 may change the setting of the radio frequency of the audio device 150 based on the first radio frequency, the received radio station information, and/or the location information of the first vehicle 100.

For instance, in response to the field strength of the first signal being equal to or less than the predetermined reference field strength, the control device 190 may identify a second radio frequency corresponding to a radio station name identical to at least one first radio station name of the first radio frequency, among the plurality of radio station names corresponding to each of the radio frequencies included in the radio station information.

The second radio frequency may be included in the at least one radio frequency identified as settable in the audio device 150 through the sub tuner 154.

The control device 190 may identify whether the first signal received through the main tuner 153 and a second signal received through the sub tuner 154 correspond to each other.

The control device 190 may change the radio frequency of the audio device 150 from the first radio frequency to the second radio frequency, in response to the identifying of the second radio frequency corresponding to the radio station name identical to the at least one first radio station name of the first radio frequency and the identifying of whether the first signal received through the main tuner 153 and the second signal received through the sub tuner 154 corresponding to each other.

For instance, the control device 190 may control the second signal of the second radio frequency to be received through the main tuner 153, and control the sound signal corresponding to the second signal to be output through the speaker 172 of the output device 170.

Meanwhile, the above-described audio device 150 and/or the output device 170 may be included in an audio video navigation (AVN) device (not shown) of the first vehicle 100. The AVN device may refer to a multimedia device where an audio, a video, a navigation and/or telematics terminals are integrated into one. The AVN device may be provided on a center fascia of the first vehicle 100, without being limited thereto.

Also, although not illustrated, the second vehicle 102 and the m^{th} vehicle 104 may include constituent components corresponding to the constituent components of the first vehicle 100 (the communication device 110, the GPS 130, the audio device 150, the output device 170, and/or the control device 190).

The server 1000 may be a big data platform of a data center, and establish a database based on big data.

The server 1000 may collect, analyze, and/or process information from each of the at least one vehicle such as the first vehicle 100, the second vehicle 102 and the m^{th} vehicle 104, to build the database for data storage and management.

For instance, information collected from each of the at least one vehicle such as the first vehicle 100, the second vehicle 102 and the m^{th} vehicle 104, may be referred to as the big data.

The server 1000 may establish a database of nationwide radio station information through big data analysis.

For example, the server 1000 may establish the database of nationwide radio station information based on a machine learning algorithm.

Referring to FIG. 2, the server 1000 may include a communicator 1002, a storage 1004 and/or a controller 1006.

The communicator 1002 (also referred to as a communication circuit) may establish wireless and/or wired communication channel between an external device such as the at least one vehicle such as the first vehicle 100, the second vehicle 102 and the m^{th} vehicle 104 and/or an electronic device (not shown) and support communication through the established communication channel.

For example, the communicator 1002 may include a communication circuit.

For example, the communicator 1002 110 may include a wired communication module (e.g., a power line communication module) and/or a wireless communication module (e.g., a cellular communication module, a WiFi communication module, and/or a local wireless communication module) and communicate with the external device using a corresponding communication module among the communication modules above.

The storage 1004 may store radio station information.

The radio station information may include location information on a plurality of transmitting stations that transmit a signal of radio frequency, radio frequencies for each of the plurality of transmitting stations, location information of a plurality of vehicles corresponding to each of the plurality of transmitting stations, and/or at least one radio station name corresponding to each of the radio frequencies.

For instance, as shown in (a) in FIG. 4, the radio station information in a form of three-dimensional (3D) radio station name (value) according to a location of each vehicle (x-axis), a location of each transmitting station (y-axis), and each frequency (z-axis) may be stored in the storage 1004.

Referring to (a) in FIG. 4, the location of each vehicle (x-axis) may include Seoul, Gyeonggi, and/or Jeju, etc., and the location of each transmitting station (y-axis) may include Seoul, Gyeonggi, Gangwon, Jeonnam and/or Jeju, etc. Also, each frequency (z-axis) may include 108.1 MHz, 87.7 MHz, and/or 87.5 MHz, etc.

For example, as shown in (b) in FIG. 4, according to the location of each vehicle, the radio station information in a form of two-dimensional (2D) radio station name (value) according to the location of each transmitting station (y-axis) in a corresponding area and each frequency (z-axis) may be stored in the storage 1004.

Referring to (b) in FIG. 4, the location of each transmitting station (y-axis) may include Seoul, Gyeonggi, Gangwon, Jeonnam and/or Jeju, etc., and each frequency (z-axis) may include 108.1 MHz, 87.7 MHz, and/or 87.5 MHz, etc.

The at least one radio station name corresponding to each of the radio frequencies and/or the location information of each of the plurality of transmitting stations may be stored in the storage 1004 in advance. For instance, the controller 1006 may receive the location information of each of the plurality of transmitting stations and/or the at least one radio station name corresponding to each of the radio frequencies, from an external server through the communicator 1002 and/or based on a user's input through an inputter (not shown), and store the at least one radio station name and/or the location information of each of the plurality of transmitting stations in the storage 1004.

The radio frequencies for each of the plurality of transmitting stations, the location information of the plurality of vehicles corresponding to each of the plurality of transmitting stations, and the at least one radio station name corresponding to each of the radio frequencies may be received from at least one vehicle and stored in the storage 1004.

The controller 1006 may receive, from each of the at least one vehicle such as the first vehicle 100, the second vehicle 102, and the m^{th} vehicle 104, location information of its own, information related to reception of a radio broadcast corresponding to the location information and/or other information.

For example, the information related to the reception of the radio broadcast may include a radio frequency, a field strength of a signal of the radio frequency, and/or a radio station name of the radio frequency, and the like.

For example, the other information may include current time information and/or vehicle information, and the like.

The controller 1006 may establish a database of the radio station information stored in the storage 1004, through big data analysis of information received from the at least one vehicle, and update the radio station information automatically and constantly.

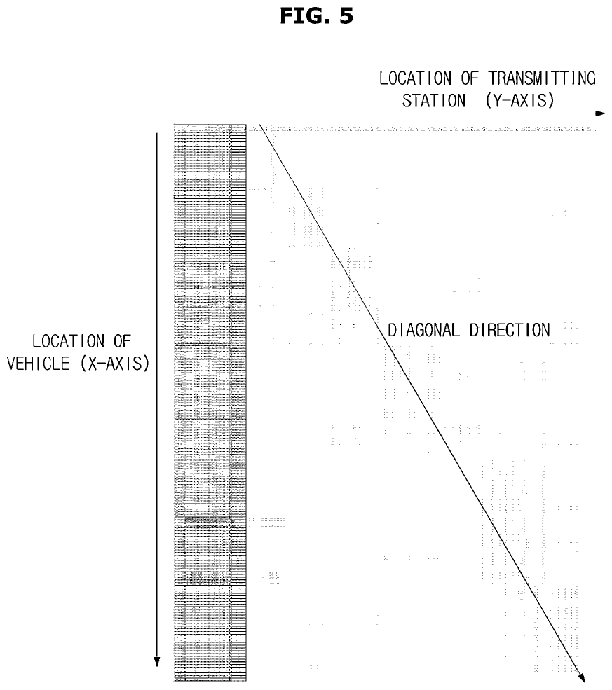

As shown in FIG. 5, the controller 1006 may implement the radio station information stored in the storage 1004 as a 2D vehicle location corresponding to a frequency signal according to a location of each vehicle (x-axis) and a location of each transmitting station (y-axis).

The controller 1006 may identify that the closer to a central diagonal direction of the location of each vehicle (x-axis) and the location of each transmitting station (y-axis), the higher field strength of a received signal is, and also the farther away from the central diagonal direction, the lower field strength of the received signal is.

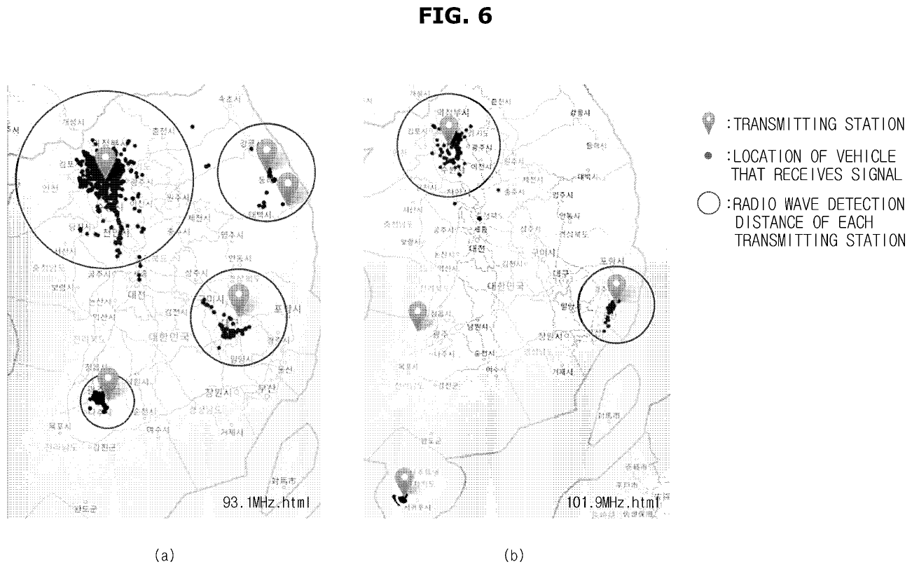

As shown in (a) and (b) in FIG. 6, based on the radio station information stored in the storage 1004, the controller 1006 may generate 2D map information in which a location of each of the transmitting stations for each of the radio frequencies, a radio wave detection area of a signal of each of the transmitting stations, and location information of each vehicle that has received a signal of each of the radio frequencies are displayed. The controller 1006 may store the 2D map information for each of the radio frequencies as the radio station information in the storage 1004.

The radio wave detection area of signal of each of the transmitting stations may be determined based on a field strength of a signal of each of the transmitting stations. For instance, the radio wave detection area of signal of each of the transmitting stations may be determined based on the field strength of the signal of each of the transmitting stations being greater than a predetermined reference value.

For example, as shown in (a) in FIG. 6, the controller 1006 may generate the 2D map information displaying locations of transmitting stations that transmit a signal of 93.1 MHz radio frequency, radio wave detection areas of each of the transmitting stations, and a location of each vehicle that receives 93.1 MHz radio frequency signal.

For example, as shown in (b) in FIG. 6, the controller 1006 may generate the 2D map information displaying locations of transmitting stations that transmit a signal of 101.9 MHz radio frequency, radio wave detection areas of each of the transmitting stations, and a location of each vehicle that receives 101.9 MHz radio frequency signal.

The controller 1006 may input information received from the at least one vehicle to a pre-trained machine learning algorithm, and update the radio station information stored in the storage 1004 automatically and constantly.

For instance, the controller 1006 may input information received from the first vehicle 100, i.e., the location information of the first vehicle 100 and a radio frequency corresponding to the location information of the first vehicle 100, to the pre-trained machine learning algorithm, and predict a first transmitting station corresponding to the location information of the first vehicle 100 among the plurality of transmitting stations stored in the storage 1004. The controller 1006 may store the location information of the first vehicle to correspond to the first transmitting station in the storage 1004 and update the radio station information.

The machine learning algorithm may include classification and clustering algorithms.

For example, the machine learning algorithm may include a K-nearest neighbors algorithm. The K-nearest neighbors algorithm is an algorithm that finds the closest point to a query point q within S regarding the query point q which is an element of a space M, given a set S of points in the M.

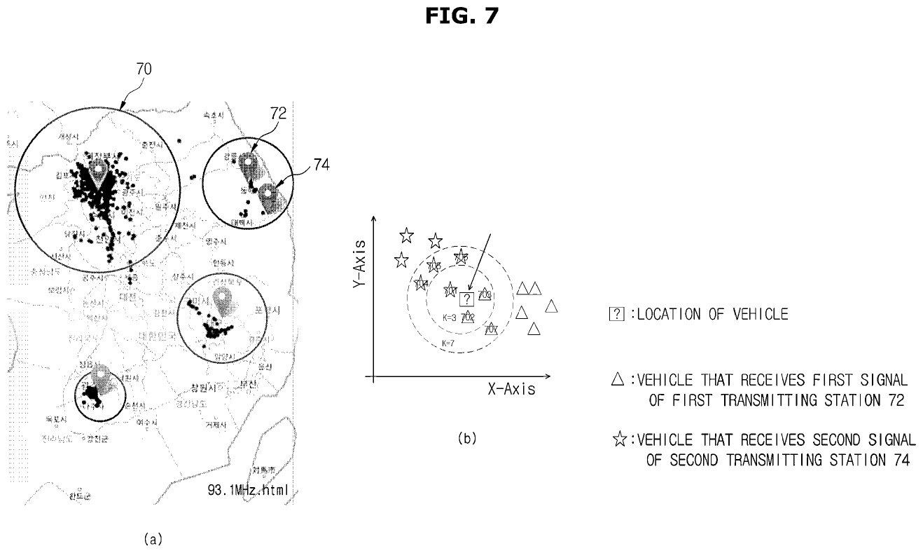

For instance, as shown in (a) in FIG. 7(a), when a radio frequency included in the information received from the first vehicle 100 is 93.1 MHz, the controller 1006 may identify 2D map information corresponding to the 93.1 MHz radio frequency from the 2D map information for each of the radio frequencies stored in advance. Alternatively, as shown in (a) in FIG. 7, the controller 1006 may generate the 2D map information corresponding to the 93.1 MHz radio frequency based on the radio station information stored in the storage 1004 and the information received from the first vehicle 100.

In general, in the 2D map information like (a) in FIG. 7, when the first vehicle 100 is located inside a radio wave detection area of one transmitting station, a transmitting station from which the first vehicle 100 receives a radio broadcast signal is easily predictable. By contrast, in the 2D map information like (a) in FIG. 7, when the first vehicle 100 is located outside of radio wave detection areas of all transmitting stations, a transmitting station from which the first vehicle 100 receives a radio broadcast signal is not easily predictable.

According to an embodiment of the disclosure, when the first vehicle 100 is located outside of predetermined radio wave detection areas of transmitting stations, the controller 1006 may determine a transmitting station from which the first vehicle 100 receives a radio broadcast signal by applying the K-nearest neighbors algorithm.

In the 2D map information like (a) in FIG. 7, when the first vehicle 100 is located outside of all radio wave detection areas, the controller 1006 may predict a transmitting station's radio wave detection area in which the first vehicle 100 will be included, i.e., may learn which transmitting station's radio broadcast signal is efficient for the first vehicle 100 to receive from, based on the pre-trained K-nearest neighbors algorithm.

For example, when the first vehicle 100 is located outside of a radio wave detection area of a transmitting station 70 of 93.1 MHz in a metropolitan area, the controller 1006 may identify a transmitting station's radio wave detection area in which other vehicles adjacent to the first vehicle 100 are included, for example, identify a radio wave detection area of which one of a first transmitting station 72 and a second transmitting station 74 where the other vehicles are included, based on the location information of the first vehicle 100.

For instance, as shown in (b) in FIG. 7, in the 2D map information, when the first vehicle 100 is located between places where vehicles that receive the first signal of the first transmitting station 72 are located and places where vehicles that receive the second signal of the second transmitting station 74 are located, the controller 1006 may determine (or predict) a transmitting station's radio wave detection area in which the first vehicle 100 is included, based on a threshold value k which is predetermined or randomly determined.

For example, when the threshold value k is 3, the controller 1006 may determine that the first vehicle 100 is included in the radio wave detection area of the first transmitting station 72 in which a larger number of vehicles are included, among three vehicles 701, 702 and 703 closest to the first vehicle 100, based on the location of the first vehicle 100.

Also, the controller 1006 stores the location of the first vehicle 100, a location of the first transmitting station 72, the radio frequency of 93.1 MHz and/or the radio station name to correspond to each other, and thereby may update the radio station information stored in the storage 1004.

As another example, when the threshold value k is 7, the controller 1006 may determine that the first vehicle 100 is included in the radio wave detection area of the second transmitting station 74 in which a larger number of vehicles are included, among seven vehicles 701, 702, 703, 704, 705, 706 and 707 closest to the first vehicle 100, based on the location of the first vehicle 100.

Also, the controller 1006 stores the location of the first vehicle 100, a location of the second transmitting station 74, the radio frequency of 93.1 MHz and/or the radio station name to correspond to each other, and thereby may update the radio station information stored in the storage 1004.

Meanwhile, in the 2D map information like (a) in FIG. 7, when the first vehicle 100 is located inside a radio wave detection area of any transmitting station, the controller 1006 may determine that the first vehicle 100 corresponds to the any transmitting station. Also, the controller 1006 stores the location of the first vehicle 100, a location of the any transmitting station, the radio frequency of 93.1 MHz and/or the radio station name to correspond to each other, and thereby may update the radio station information stored in the storage 1004.

The controller 1006 may transmit the updated radio station information to each of the at least one vehicle such as the first vehicle 100, the second vehicle 102, and the m^{th} vehicle 104, through the communicator 1002.

Hereinafter, the first vehicle 100 is described as a vehicle 100.

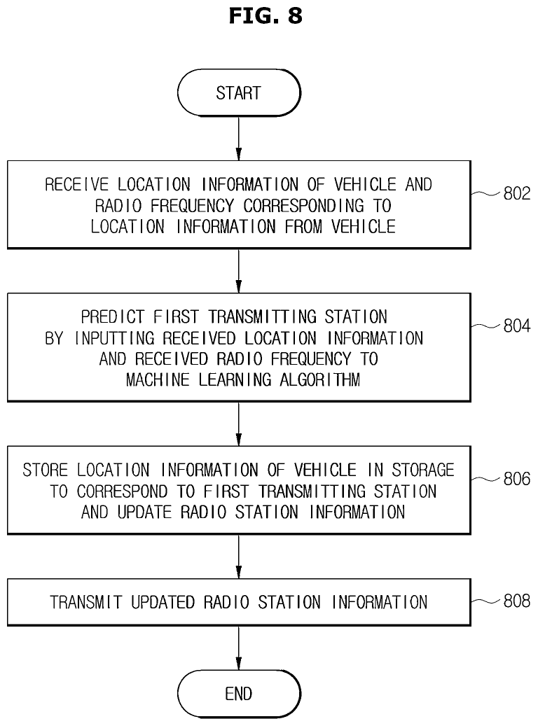

FIG. 8 is a flowchart illustrating operations of the server 1000 (and/or the controller 1006 of the server 1000) according to an embodiment.

The server 1000 may receive location information of the vehicle 100 and a radio frequency corresponding to the location information, from the vehicle 100 (802).

The server 1000 may predict a first transmitting station by inputting the location information and the radio frequency received from the vehicle 100 to a pre-trained machine learning algorithm (804).

The server 1000 may predict the first transmitting station corresponding to the location information received from the vehicle 100 among a plurality of transmitting stations stored in the server 1000 in advance.

Radio station information may be stored in the server 1000. The radio station information includes location information on the plurality of transmitting stations, radio frequencies for each of the plurality of transmitting stations, location information of a plurality of vehicles corresponding to each of the plurality of transmitting stations, and at least one radio station name corresponding to each of the radio frequencies.

The pre-trained machine learning algorithm may include a K-nearest neighbors algorithm.

The machine learning algorithm may identify at least one transmitting station of the same radio frequency, i.e., at least one transmitting station corresponding to a received radio frequency, among the plurality of transmitting stations stored in the server 1000 in advance.

For example, when a radio frequency received from the vehicle 100 is 93.1 MHz, the machine learning algorithm may identify transmitting stations of 93.1 MHz radio frequency among the plurality of transmitting stations stored in the server 1000 in advance.

Also, when the location information received from the vehicle 100 is included in a predetermined first radio wave detection area of the first transmitting station among the at least one transmitting station, the machine learning algorithm may be pre-trained to predict that the first transmitting station corresponds to the location information received from the vehicle 100.

Also, when the location information received from the vehicle 100 is not included in a predetermined radio wave detection area of each of the at least one transmitting stations, the machine learning algorithm may identify a predetermined number of vehicles located adjacent to the location information received from the vehicle 100, among vehicles corresponding to each of the at least one transmitting stations. The machine learning algorithm may be pre-trained to predict that the first transmitting station in which a largest number of vehicles are included among the identified vehicles corresponds to the location information received from the vehicle 100.

For example, when the predetermined number is 5 and it is identified that the predetermined number of vehicles located adjacent to the received location information are three vehicles corresponding to the first transmitting station and two vehicles corresponding to the second transmitting station, the machine learning algorithm may be pre-trained to predict that the first transmitting station corresponds to the location information received from the vehicle 100.

The server 1000 may store the location information of the vehicle 100 to correspond to the first transmitting station in the storage 1004 and update the radio station information (806).

The server 1000 may transmit the updated radio station information to the vehicle 100 (808).

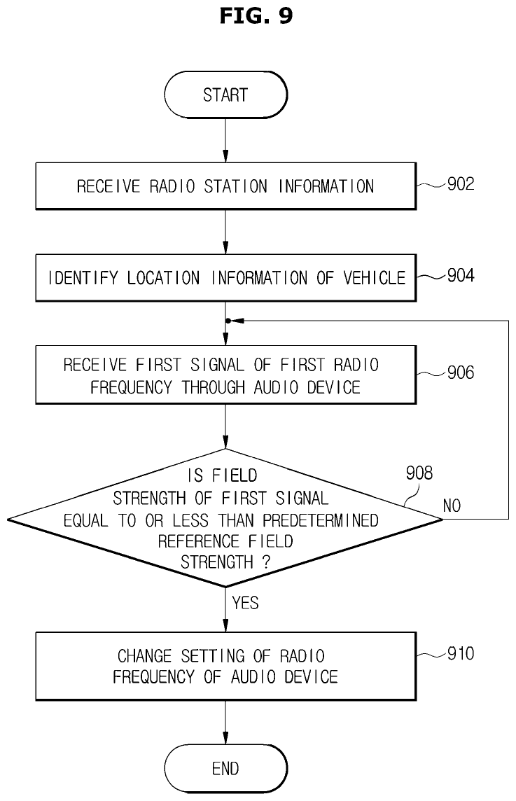

FIG. 9 is a flowchart illustrating operations of the vehicle 100 (and/or the control device 190 of the vehicle 100) according to an embodiment.

The vehicle 100 may receive radio station information from the server 1000 through the communication device 110 (902).

The radio station information may include information on a plurality of areas, radio frequencies for each of the plurality of areas, and/or a plurality of radio station names corresponding to each of the radio frequencies.

The vehicle 100 may identify location information of the vehicle 100 based on a signal received through the GPS 130 (904).

The vehicle 100 may receive a first signal of a first radio frequency through the audio device 150 (906).

The vehicle 100 may receive the first signal through the main tuner 153 of the audio device 150, and identify at least one radio frequency settable in the audio device 150 through the sub tuner 154.

The vehicle 100 may identify whether a field strength of the first signal is equal to or less than a predetermined reference field strength (908).

When the field strength of the first signal is equal to or less than the predetermined reference field strength, the vehicle 100 may perform an operation 910. Otherwise, the vehicle 100 may perform an operation 906 again.

The vehicle 100 may change a setting of a radio frequency of the audio device 150 based on the first radio frequency, the radio station information, and/or location information of the vehicle 100 (910).

In response to the field strength of the first signal being equal to or less than the predetermined reference field strength, the vehicle 100 may identify a second radio frequency corresponding to a radio station name identical to at least one first radio station name of the first radio frequency, among a plurality of radio station names corresponding to each of the radio frequencies included in the radio station information.

The vehicle 100 may change the radio frequency of the audio device 150 from the first radio frequency to the second radio frequency, in response to the identifying of the second radio frequency.

When failing to identify a radio frequency corresponding to the radio station name identical to the first radio station name, e.g., the second radio frequency, the vehicle 100 may output information related to the above through the output device 170. For example, the vehicle 100 may output information indicating that the radio broadcast a user was listening to may not be provided, through the output device 170.

For instance, the vehicle 100 may identify the at least one first radio station name corresponding to the first radio frequency based on the radio station information. Also, the vehicle 100 may identify at least one second radio station name corresponding to each of the at least one radio frequencies identified to be settable in the audio device 150 through the sub tuner 154, based on the radio station information.

For instance, the vehicle 100 may identify the second radio frequency corresponding to the radio station name identical to the at least one first radio station name of the first radio frequency, among the at least one second radio station name corresponding to each of the at least one radio frequencies.

Also, the vehicle 100 may change the radio frequency of the audio device 150 from the first radio frequency to the second radio frequency, based on the first signal received through the main tuner 153 and a second signal received through the sub tuner 154 corresponding to each other.

For instance, in response to changing the radio frequency of the audio device 150 from the first radio frequency to the second radio frequency, the vehicle 100 may receive the second signal of the second radio frequency through the main tuner 153. The vehicle 100 may control the output device 170 to output a signal corresponding to the second signal.

When the first signal received through the main tuner 153 and the second signal received through the sub tuner 154 do not correspond to each other, the vehicle 100 may output information indicating that the same radio broadcast that the user was listening to may not be provided, through the output device 170.

Meanwhile, in addition to the above-described embodiments, the vehicle 100 may identify (or monitor) the radio station information stored in the server 1000 in real time.

For example, according to the location information of the vehicle 100, the vehicle 100 may identify the radio station information in a form of 2D radio station name (value) according to a location of each transmitting station (y-axis) and each frequency (z-axis), e.g., a radio station list in a corresponding area as shown in (b) in FIG. 4.

When the field strength of the first radio frequency of the first signal that is currently being received is equal to or less than the predetermined reference field strength (or an average value of the field strengths of the first radio frequency for a predetermined period of time is equal to or less than the predetermined reference field strength), the vehicle 100 may identify the same radio station as a first radio station of the first radio frequency, in the radio station information in a form of 2D radio station name (value) according to a location of each transmitting station (y-axis) and each frequency (z-axis) in an area corresponding to current location information of the vehicle 100. The vehicle 100 may generate a receivable frequency list based on the same radio station as the first radio station of the first radio frequency.

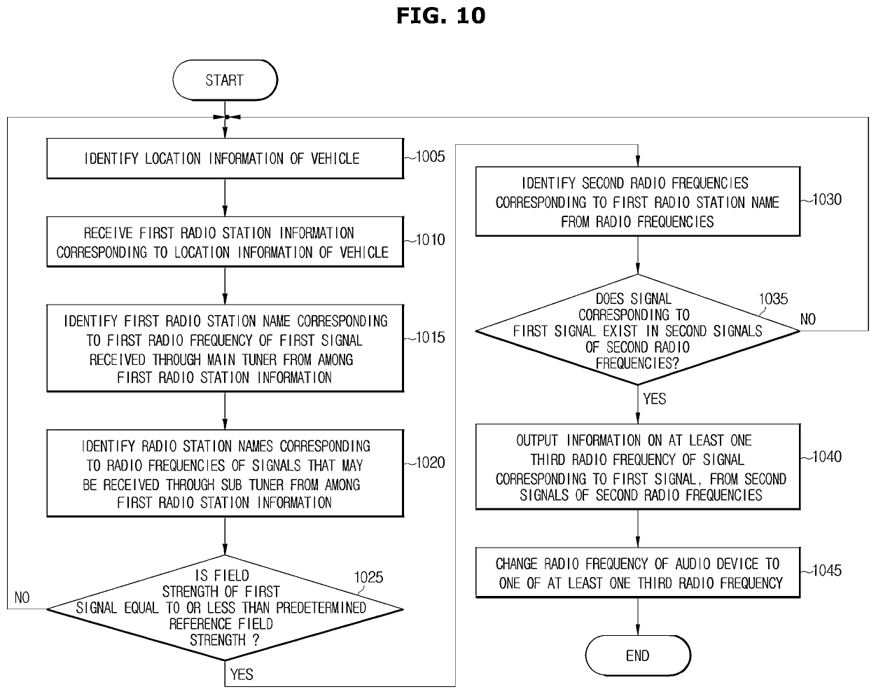

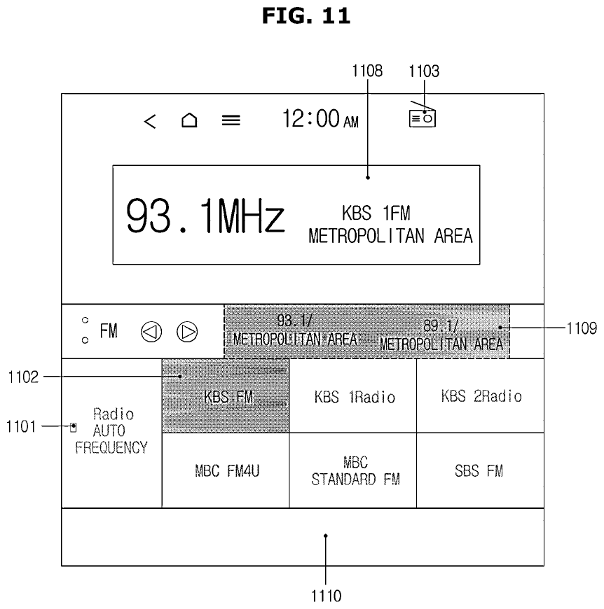

FIG. 10 is a flowchart illustrating operations of the vehicle 100 (and/or the control device 190 of the vehicle 100) according to an embodiment. FIG. 11 is a diagram illustrating a screen of the display 174 of the audio device 150 of the vehicle 100 according to an embodiment.

Referring to FIG. 10, the vehicle 100 may identify location information of the vehicle 100 (1005).

The vehicle 100 may receive first radio station information corresponding to the location information of the vehicle 100 from the server 1000 (1010).

The first radio station information may include information on a plurality of areas, radio frequencies for each of the plurality of areas, and/or a plurality of radio station names corresponding to each of the radio frequencies.

The information on the plurality of areas may correspond to location information of each vehicle and each of the radio frequencies may correspond to each transmitting station.

For example, the first radio station information may include information in a form of lookup table in which each frequency corresponding to a current location and a radio station name are matched.

The vehicle 100 may identify a first radio station name corresponding to a first radio frequency of a first signal received through the main tuner 153 from among the first radio station information (1015).

The vehicle 100 may identify radio station names corresponding to radio frequencies of signals that may be received through the sub tuner 154 from among the first radio station information (1020).

The vehicle 100 may identify whether a field strength of the first signal of the first radio frequency is equal to or less than a reference field strength (1025).

The vehicle 100 may perform an operation 1030 in response to the field strength of the first signal being equal to or less than the reference field strength. Otherwise, the vehicle 100 may perform an operation 1005 again.

The vehicle 100 may identify second radio frequencies corresponding to the first radio station name from the radio frequencies of the signals that may be received through the sub tuner 154 (1030).

The vehicle 100 may identify whether a signal corresponding to the first signal exists in second signals of the second radio frequencies (1035).

In response to the signal corresponding to the first signal existing in the second signals of the second radio frequencies, the vehicle 100 may perform an operation 1040. Otherwise, the vehicle 100 may perform the operation 1005 again.

The vehicle 100 may output information on at least one third radio frequency of a signal corresponding to the first signal, i.e., the signal identical to the first signal, from the second signals of the second radio frequencies (1040).

For instance, the vehicle 100 may output a radio frequency list of the same signal as the first signal.

For instance, the vehicle 100 may output a screen shown in FIG. 11 on the display 174.

Referring to FIG. 11, on the display 174, menu items such as a mode display 1101, a list of nationwide radio stations 1102, a radio mode 1103, a frequency lock 1104, a radio recording 1105, a GPS activation display 1106, a stereo display 1107, a broadcast/area display 1108, a frequency list 1109, a broadcast status guide 1110, a reservation listening 1111 and a Back 1112 may be displayed.

For example, the mode display 1101 may display an auto radio frequency mode currently running.

The list of nationwide radio stations 1102 may indicate that six nationwide radio broadcasts, i.e., Korean broadcasting system frequency modulation (KBS FM), KBS 1Radio, KBS 2Radio, Munhwa broadcasting system (MBC) FM4U, MBC standard FM, and Seoul broadcasting system (SBS) FM, are available.

The radio mode 1103 may be a button for changing to a basic radio mode set by a user after ending an automatic frequency mode.

The frequency lock 1104 may be a button for fixing a single frequency by the user when two or more frequencies exist in an area where the vehicle is located.

The radio recording 1105 may be a button for recording a radio broadcast currently listening to.

The GPS activation display 1106 may indicate whether a GPS is activated.

The stereo display 1107 may indicate whether a stereo sound is reproduced.

The broadcast/area display 1108 may display a radio station name that the user is currently listening to and a current area.

The frequency list 1109 may be a list of frequencies that radio stations transmit. For example, the frequency list 1109 may indicate a list of radio frequencies of the same signal as the first signal.

The broadcast status guide 1110 may be a guide text when a reception sensitivity of radio broadcast is low.

The reservation listening 1111 may be a function for reservation setting of a radio broadcast that the user is currently listening to.

The Back 1112 may be a function for switching to a previous screen.

The vehicle 100 may change a radio frequency of the audio device 150 to one of at least one third radio frequency (1045).

For example, the vehicle 100 may change the radio frequency of the audio device 150 to one of the at least one third radio frequency by a user's selection or automatically.

In the operation 1035 described above, when the signal corresponding to the first signal does not exist in the signals of the second radio frequencies, the vehicle 100 may output information indicating that the radio broadcast that the user is currently listening to may not be provided, through the output device 170.

Meanwhile, each local transmitting station of a single radio station has different radio frequencies, but different radio programs (or content) may be scheduled per time.

For example, for transmitting stations of SBS Power FM, although a first program starting at 2 pm on SBS Power FM is the same, a second program starting at 4 pm on SBS Power FM may be different for each of the transmitting stations of SBS Power FM.

Conventionally, when radio programs aired per time in each local transmitting station of a single radio station are different, the different radio programs may not be distinguished.

According to the above-described embodiments, however, by comparing two audio signals, e.g., the first signal and the second signal, before changing the radio frequency of the audio device 150, the vehicle 100 may identify whether the two audio signals are audio signals of the same radio program or audio signals of different radio programs. Also, the when the two audio signals are audio signals of the same radio program, the vehicle 100 may automatically change the radio frequency.

Meanwhile, in addition to the above-described embodiments, the vehicle 100 may perform switching between radio broadcasts having different modulation schemes.

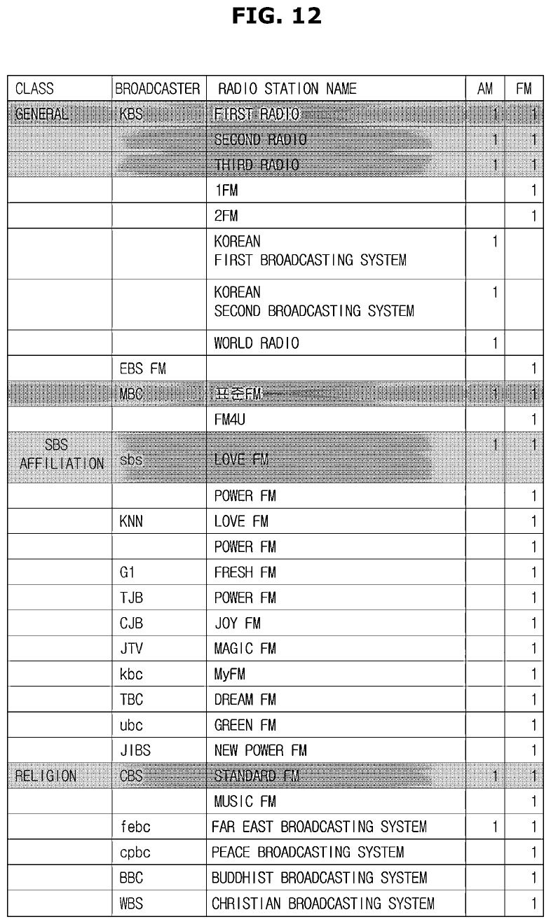

For instance, as shown in FIG. 12, whether a radio broadcast corresponding to each radio station name of each radio station includes only amplitude modulation (AM) broadcast, only FM broadcast, or both AM and FM broadcasts may be stored in the storage 1004 of the server 1000.

FIG. 12 is a diagram illustrating radio station information according to an embodiment.

Referring to FIG. 12, the server 1000 may identify that KBS 1Radio, KBS 2Radio, and KBS 3Radio of KBS, MBC standard FM of MBC, and LoveFM of SBS include both AM broadcast and FM broadcast.

For example, the vehicle 100 may perform a radio frequency change (also referred to as a radio frequency switch) among FM radio broadcasts, and also perform a radio frequency change among AM radio broadcasts and FM radio broadcasts based on radio station information stored in the storage 1004 of the server 1000, as shown in FIG. 12. Accordingly, the vehicle 100 may provide a wider range of choices of radio frequency.

For instance, the vehicle 100 may select a radio frequency of a stable signal reception state among radio frequencies of the AM radio broadcasts and the FM radio broadcasts, and change to a radio frequency of the selected radio broadcast.

Also, in addition to the above-described embodiments, the vehicle 100 may output a radio broadcast through an online radio application.

When an online radio application may be installed in the vehicle 100, an application for each radio station or an application capable of providing broadcasts of a plurality of radio stations may be installed in the vehicle 100, e.g., in an AVN device of the vehicle 100, through manipulation by a user.

In a state where the online radio application is installed in the vehicle 100, when a field strength of signal of the AM radio broadcast and/or FM radio broadcast output through the audio device 150 of the vehicle 100 is equal to or less than a reference field strength and no AM and/or FM radio broadcast signals having field strength acceptable to operations of the vehicle 100 exist, an application capable of providing a radio broadcast of a radio station of a radio broadcast that a user was currently listening to may be executed. The vehicle 100 may output an online radio broadcast corresponding to the radio broadcast that the user was currently listening to through the online radio application. In this instance, an output of the radio broadcast that the user was currently listening to may end.

For online radio broadcasting, because a field strength of signal of nationwide mobile communication network is generally more appropriate than a field strength of AM and FM signals and a digital based service is provided, the vehicle 100 may receive the online radio broadcast with stable reception conditions, compared to AM and/or FM radio broadcasts. However, in relation to mobile charges, restrictions on data use and additional charge may occur. Accordingly, the vehicle 100 may be provided with a radio broadcast service through AM and/or FM radio broadcast when broadcast coverage is available.

As is apparent from the above, according to the embodiments of the disclosure, the vehicle, the server, the control method of the vehicle and the control method of the server can, when a signal received from a transmitting station in a first area of a radio broadcast is weakened due to a movement of the vehicle which is driving, automatically search for a frequency of the radio broadcast of a transmitting station in a second area of the same broadcasting station as the radio broadcast that an occupant is currently listening to, change to the searched frequency, and thereby may allow the occupant to continuously listen to the radio broadcast that the occupant is currently listening to.

For instance, the vehicle, the server, the control method of the vehicle and the control method of the server can provide a radio frequency switching technique with high accuracy.

For instance, the vehicle, the server, the control method of the vehicle and the control method of the server can provide a user with a service such as notifying the user that transmitting stations in each area of a radio station transmit different radio programs (also referred to as content) per time by classifying audio signals.

Embodiments can thus be implemented through computer readable code/instructions in/on a medium, e.g., a non-transitory computer readable medium, to control at least one processing element to implement any above described exemplary embodiment. For example, the aforementioned processor (or controller) may be configured to perform various operations when executing the computer readable code/instructions. The medium can correspond to any medium/media permitting the storing and/or transmission of the computer readable code.

The computer-readable code can be recorded on a medium or transmitted through the Internet. The medium may include read only memory (ROM), random access memory (RAM), magnetic tapes, magnetic disks, flash memories, and optical recording medium.

Although embodiments have been described for illustrative purposes, those skilled in the art will appreciate that various modifications, additions and substitutions are possible, without departing from the scope and spirit of the disclosure. Therefore, embodiments have not been described for limiting purposes.

What is claimed is:

1. A vehicle, comprising:
a communication device;
an audio device;
a global positioning system; and
a control device configured to:
receive radio station information from a server through the communication device, the radio station information including information on a plurality of areas, radio frequencies for each of the plurality of areas, and a plurality of radio station names corresponding to each of the radio frequencies,
identify location information of the vehicle based on a signal received through the global positioning system,
receive a first signal of a first radio frequency through the audio device, and
change a setting of a radio frequency of the audio device, based on the first radio frequency, the radio station information, and the location information of the vehicle, in response to a field strength of the first signal being equal to or less than a reference field strength.

2. The vehicle of claim 1, wherein the control device is configured to:
identify a second radio frequency corresponding to a radio station name identical to at least one first radio station name of the first radio frequency, among the plurality of radio station names corresponding to each of the radio frequencies included in the radio station information, in response to the field strength of the first signal being equal to or less than the reference field strength, and
change the radio frequency of the audio device from the first radio frequency to the second radio frequency, in response to the identifying of the second radio frequency.

3. The vehicle of claim 2, wherein the audio device comprises a main tuner and a sub tuner,
the first signal is received through the main tuner, and
the control device is configured to:
identify at least one radio frequency settable in the audio device through the sub tuner,
identify at least one second radio station name corresponding to each of the at least one radio frequencies, based on the radio station information, and
identify the second radio frequency corresponding to the radio station name identical to the at least one first radio station name of the first radio frequency, among the at least one second radio station name corresponding to each of the at least one radio frequencies, in response to the field strength of the first signal being equal to or less than the reference field strength.

4. The vehicle of claim 3, wherein the control device is configured to identify the at least one first radio station name corresponding to the first radio frequency based on the radio station information.

5. The vehicle of claim 3, wherein a second signal of the second radio frequency is received through the sub tuner, and
the control device is configured to change the radio frequency of the audio device from the first radio frequency to the second radio frequency based on the first signal and the second signal corresponding to each other.

6. The vehicle of claim 5, further comprising:
an output device, and
wherein the control device is configured to:
receive the second signal of the second radio frequency through the main tuner, in response to changing the radio frequency of the audio device from the first radio frequency to the second radio frequency, and
control the output device to output a signal corresponding to the second signal.

7. A server, comprising:
a communicator;
a storage configured to store radio station information including location information on a plurality of transmitting stations, radio frequencies for each of the plurality of transmitting stations, location information of a plurality of vehicles corresponding to each of the plurality of transmitting stations, and at least one radio station name corresponding to each of the radio frequencies; and
a controller configured to:
receive location information of a vehicle and a radio frequency corresponding to the location information of the vehicle, from the vehicle through the communicator,
run a machine learning algorithm which is pre-trained to predict, based on the received location information and the received radio frequency, a first transmitting station corresponding to the received location information among the plurality of transmitting stations,
store the location information of the vehicle in the storage to correspond to the first transmitting station and update the radio station information, and
transmit the updated radio station information to the vehicle through the communicator.

8. The server of claim 7, wherein the controller is configured to run the machine learning algorithm to identify at least one transmitting station corresponding to the received radio frequency among the plurality of transmitting stations, and to predict that the first transmitting station corresponds to the received location information, in response to the received location information being included in a predetermined first radio wave detection area of the first transmitting station among the at least one transmitting station.

9. The server of claim 8, wherein the controller is configured to run the machine learning algorithm to identify a predetermined number of vehicles located adjacent to the received location information among vehicles corresponding to each of the at least one transmitting stations, in response to the received location information not being included in a predetermined radio wave detection area of each of the at least one transmitting stations, and to predict that the first transmitting station in which a largest number of vehicles are included among the identified vehicles corresponds to the received location information.

10. The server of claim 7, wherein the machine learning algorithm includes a K-nearest neighbors algorithm.

11. A control method of a vehicle, the control method comprising:
receiving, from a server, radio station information including information on a plurality of areas, radio frequencies for each of the plurality of areas, and a plurality of radio station names corresponding to each of the radio frequencies,
identifying location information of the vehicle based on a signal received through a global positioning system of the vehicle,
receiving a first signal of a first radio frequency through an audio device of the vehicle, and
changing a setting of a radio frequency of the audio device, based on the first radio frequency, the radio station information, and the location information of the vehicle, in response to a field strength of the first signal being equal to or less than a reference field strength.

12. The control method of claim 11, wherein the changing of the setting of the radio frequency of the audio device comprises:
identifying a second radio frequency corresponding to a radio station name identical to at least one first radio station name of the first radio frequency, among the plurality of radio station names corresponding to each of the radio frequencies included in the radio station information, in response to the field strength of the first signal being equal to or less than the reference field strength, and
changing the radio frequency of the audio device from the first radio frequency to the second radio frequency, in response to the identifying of the second radio frequency.

13. The control method of claim 12, wherein the first signal is received through a main tuner of the audio device,
the control method further comprises:
identifying at least one radio frequency settable in the audio device through a sub tuner of the audio device, and
identifying at least one second radio station name corresponding to each of the at least one radio frequencies, based on the radio station information, and
the identifying of the second radio frequency comprises:
identifying the second radio frequency corresponding to the radio station name identical to the at least one first radio station name of the first radio frequency, among the at least one second radio station name corresponding to each of the at least one radio frequencies, in response to the field strength of the first signal being equal to or less than the reference field strength.

14. The control method of claim 13, wherein the identifying of the second radio frequency comprises:
identifying the at least one first radio station name corresponding to the first radio frequency based on the radio station information.

15. The control method of claim 13, wherein a second signal of the second radio frequency is received through the sub tuner, and
the changing of the setting of the radio frequency of the audio device changes the radio frequency of the audio device from the first radio frequency to the second radio frequency based on the first signal and the second signal corresponding to each other.

16. The control method of claim 15, further comprising:
receiving the second signal of the second radio frequency through the main tuner, in response to changing the radio frequency of the audio device from the first radio frequency to the second radio frequency, and
controlling an output device of the vehicle to output a signal corresponding to the second signal.

17. A control method of a server, the control method comprising:
storing radio station information including location information on a plurality of transmitting stations, radio frequencies for each of the plurality of transmitting stations, location information of a plurality of vehicles corresponding to each of the plurality of transmitting stations, and at least one radio station name corresponding to each of the radio frequencies;
receiving, from a vehicle, location information of the vehicle and a radio frequency corresponding to the location information of the vehicle;
running a machine learning algorithm which is pre-trained to predict, based on the received location information and the received radio frequency, a first transmitting station corresponding to the received location information among the plurality of transmitting stations;
storing the location information of the vehicle in a storage to correspond to the first transmitting station and updating the radio station information; and
transmitting the updated radio station information to the vehicle.

18. The control method of claim 17, wherein the running of the machine learning algorithm comprises:
identifying at least one transmitting station corresponding to the received radio frequency among the plurality of transmitting stations, and
predicting that the first transmitting station corresponds to the received location information, in response to the received location information being included in a predetermined first radio wave detection area of the first transmitting station among the at least one transmitting station.

19. The control method of claim 18, wherein the running of the machine learning algorithm comprises:
identifying a predetermined number of vehicles located adjacent to the received location information among vehicles corresponding to each of the at least one transmitting stations, in response to the received location information not being included in a predetermined radio wave detection area of each of the at least one transmitting stations, and
predicting that the first transmitting station in which a largest number of vehicles are included among the identified vehicles corresponds to the received location information.

20. The control method of claim 17, wherein the machine learning algorithm includes a K-nearest neighbors algorithm.
